(19) United States
(12) Patent Application Publication
(10) Pub. No.: US 2025/0079193 A1
(43) Pub. Date: Mar. 6, 2025

(54) SUBSTRATE PROCESSING APPARATUS

(71) Applicant: TES CO., LTD, Yongin-si (KR)

(72) Inventors: In-Il JUNG, Yongin-si (KR); Hyeong-Wook Moon, Yongin-si (KR); Seung-Min OH, Yongin-si (KR); Jong-Seok LEE, Yongin-si (KR)

(73) Assignee: TES CO., LTD, Yongin-si (KR)

(21) Appl. No.: 18/815,854

(22) Filed: Aug. 27, 2024

(30) Foreign Application Priority Data
Aug. 28, 2023 (KR) 10-2023-0112589

(51) Int. Cl. H01L 21/67; H01J 37/32

(52) U.S. Cl. CPC H01L 21/67017; H01J 37/3244; H01J 2237/3355

(57) ABSTRACT

Provided are a substrate processing apparatus and a substrate processing method, and more specifically, a substrate processing apparatus and a substrate processing method for easily cleaning an unnecessary thin film deposited on a lower surface and edge area of a substrate without inverting the substrate.

### CROSS-REFERENCE TO RELATED APPLICATION

This application is based on and claims priority under 35 U.S.C. § 119 to Korean Patent Application No. 10-2023-0112589, filed on Aug. 28, 2023, in the Korean Intellectual Property Office, the disclosure of which is incorporated by reference herein in its entirety.

### TECHNICAL FIELD

The present disclosure relates to a substrate processing apparatus and a substrate processing method, and more particularly, to a substrate processing apparatus and a substrate processing method for easily cleaning an unnecessary thin film deposited on a lower surface and bevel area of a substrate without inverting the substrate.

### BACKGROUND

During a semiconductor manufacturing process in which a thin film or the like is deposited on an upper surface of a substrate, an unnecessary thin film may also be formed on a lower surface or bevel area of the substrate. The thin film formed on the lower surface or bevel of the substrate as such may apply compressive stress or tensile stress to the substrate, which may cause a bowing phenomenon to occur in the substrate.

When the substrate bows as such, it is difficult to position the substrate at a correct position when performing processing on the substrate in various subsequent substrate processing processes. In particular, the precision of the processing process on the substrate has increased day by day, and this bowing phenomenon reduces the precision of the processing process.

To remove the thin film on the lower surface or bevel of the substrate described above, in an apparatus according to the related art, the substrate is inverted or raised and processed.

However, when the substrate is inverted, there is a problem that the overall configuration of the apparatus is very complex and the number of processes increases because a component for inverting the substrate is required. When the substrate is raised and processed, a contact area of components for raising the substrate is inevitably generated on the lower surface of the substrate, and there is a problem that the contact area is not cleaned.

### SUMMARY

To overcome the above problem, an object of the present disclosure is to provide a substrate processing apparatus for effectively cleaning a lower surface and bevel of a substrate with a simple configuration without requiring a separate component for inverting or raising the substrate.

An object of the present disclosure is to provide a substrate processing apparatus that does not invert the substrate and further does not generate a cleaning failure area on the lower surface of the substrate.

The objects of the present disclosure may be achieved by a substrate processing apparatus including a chamber providing a processing space for a substrate, an upper showerhead provided in the chamber configured to supply an inert gas toward an upper surface of the substrate and to which radio frequency (RF) power is applied, and a substrate supporting member that supports a lower surface of an edge of the substrate to supply a process gas toward a lower surface of the substrate and cleans the lower surface and bevel of the substrate by using plasma, wherein the substrate supporting member includes a substrate holder configured to support the lower surface of the edge of the substrate and a lower showerhead configured to supply the process gas toward the lower surface of the substrate, and the substrate holder includes a floating unit configured to float the substrate.

The floating unit may include a plurality of supply holes provided in a support surface supporting the substrate in the substrate holder and configured to supply a floating gas toward the lower surface of the substrate, and a gas supply line configured to supply the floating gas to the supply holes.

The plurality of supply holes of the floating unit may be divided into a plurality of supply areas.

The plurality of supply areas may be alternately arranged along a circumferential direction with respect to a central portion of the substrate holder.

Each supply areas of the plurality of supply areas may alternately supply the floating gas.

In this case, when each supply area of the plurality of supply areas alternately supply the floating gas and the process gas supplied by the lower showerhead cleans the lower surface of the substrate, the process gas may be supplied to a space between the substrate holder and the lower surface of the substrate in the supply area in which the floating gas is not supplied and cleans the bevel of the substrate.

Lengths of arcs of the plurality of supply areas may be equal to each other or at least one length of the arcs of the plurality of supply areas may be different.

Directions of the floating gases supplied from the plurality of supply areas may be the same or different from each other.

The objects of the present disclosure may be achieved by a substrate processing method of cleaning a lower surface and bevel of a substrate, the method including loading the substrate on a substrate holder, lifting the substrate to a process height, supplying an inert gas toward an upper surface of the substrate, floating the substrate by supplying a floating gas toward the lower surface of the substrate, and cleaning the lower surface and bevel of the substrate by supplying a process gas toward the lower surface of the substrate.

The floating of the substrate by supplying the floating gas toward the lower surface of the substrate may include supplying the floating gas toward a lower surface of the edge of the substrate through a plurality of supply holes formed in the substrate holder.

The plurality of supply holes may be divided into a plurality of supply areas and the plurality of supply areas are alternately arranged along a circumferential direction with respect to a central portion of the substrate holder, and the floating gas may be alternately supplied to the lower surface of the substrate in the plurality of supply areas.

The supplying of the process gas toward the lower surface of the substrate may include supplying the process gas to a space between the substrate holder and the lower surface of the substrate in the supply area in which the floating gas is not supplied and cleaning the bevel of the substrate.

The method may further include generating plasma on the lower surface of the substrate.

### BRIEF DESCRIPTION OF THE DRAWINGS

Embodiments will be more clearly understood from the following detailed description taken in conjunction with the accompanying drawings in which:

FIG. 1 is a cross-sectional side view of a substrate processing apparatus according to an embodiment of the present disclosure;

FIG. 2 is a partially enlarged diagram showing a floating unit in FIG. 1;

FIG. 3 is a plan view of a substrate holder according to an embodiment;

FIGS. 4 and 5 are plan views of a substrate holder according to another embodiment; and

FIG. 6 is a side view showing a state in which a substrate is floated in a non-contact manner by a floating unit.

### DETAILED DESCRIPTION OF THE EMBODIMENTS

Hereinafter, a structure of a substrate processing apparatus 1000 according to an embodiment of the present disclosure will be described in detail with reference to the drawings.

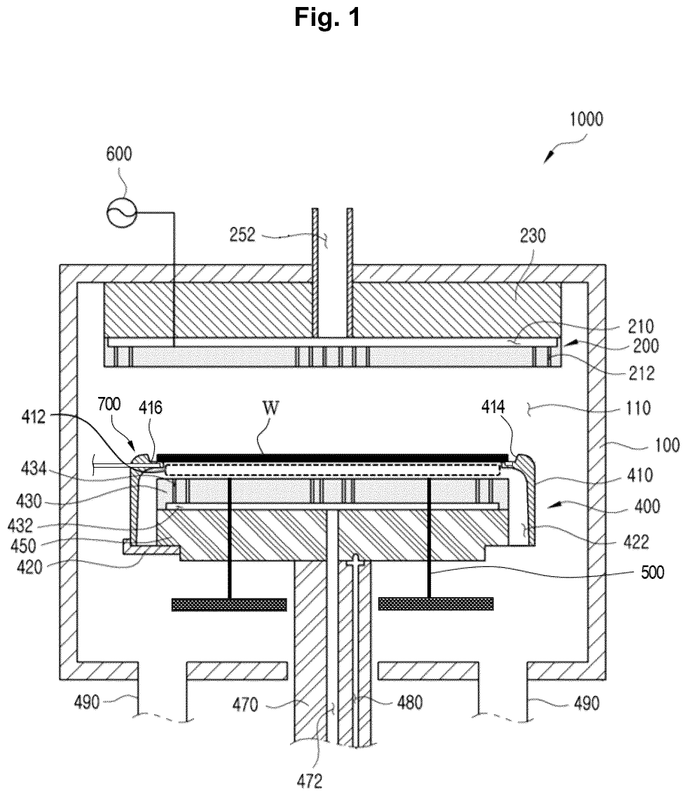

FIG. 1 is a cross-sectional side view of a substrate processing apparatus 1000 according to an embodiment of the present disclosure and shows the internal configuration.

During a semiconductor manufacturing process in which a thin film or the like is deposited on an upper surface of a substrate W, an unnecessary thin film may also be formed on a lower surface or bevel area of the substrate W. The thin film formed on the lower surface or bevel of the substrate W in this way may apply compressive stress or tensile stress to the substrate W, which may cause a bowing phenomenon to occur in the substrate W. When the substrate W bows as such, it is difficult to position the substrate W at a correct position when performing processing on the substrate W in various subsequent substrate processing processes. In particular, the precision of the processing process on the substrate W has increased day by day, and this bowing phenomenon reduces the precision of the processing process.

To remove the thin film on the lower surface or bevel of the substrate W described above, in an apparatus according to the related art, the substrate is inverted or raised and processed. However, when the substrate is inverted, there is a problem that the overall configuration of the apparatus is very complex and the number of processes increases because a component for inverting the substrate is required. When the substrate is raised and processed, a contact area of components for raising the substrate is inevitably generated on the lower surface of the substrate, and there is a problem that the contact area is not cleaned. The present disclosure is to provide a substrate processing apparatus for cleaning the lower surface and bevel of the substrate and resolving the problems described above.

Referring to FIG. 1, the substrate processing apparatus 1000 may include a chamber 100 providing a processing space 110 therein, an upper showerhead 200 provided in the chamber 100 configured to supply an inert gas toward an upper surface of the substrate W and to which RF power is applied, and a substrate supporting member 400 that supports a lower surface of an edge of the substrate W to supply a process gas toward the lower surface of the substrate W and cleans the lower surface and bevel of the substrate W by using plasma. An edge as described herein includes an annular region surrounding an activation region of the substrate W and a beveled portion of the substrate W.

The chamber 100 may provide the processing space 110 therein in which various processing processes for the substrate W are performed.

An opening (not shown) through which the substrate W is loaded into or unloaded from the processing space 110 may be provided at one side of the chamber 100 and the opening described above may include a door (not shown).

The upper showerhead 200 that supplies an inert gas such as N₂ toward the upper surface of the substrate W may be provided at an upper portion of the chamber 100. An upper heater 230 for heating the processing space 110 may be provided at an upper portion of the inside of the chamber 100.

An upper supply path 252 through which an inert gas or the like is supplied may be provided at the upper portion of the chamber 100.

The inert gas supplied along the upper supply path 252 is supplied to the upper showerhead 200 through an upper diffusion portion 210.

The inert gas supplied to the upper showerhead 200 is supplied to the upper surface of the substrate W, thereby preventing the process gas from flowing into the upper surface of the substrate W when performing a cleaning process on the lower surface of the substrate W.

The upper heater 230 for heating the processing space 110 may be provided at an upper side of the inside of the chamber 100. The upper supply path 252 described above may be formed to pass through the upper heater 230. The upper showerhead 200 may be connected to a lower side of the upper heater 230.

The upper diffusion portion 210 described above may be provided between the upper showerhead 200 and the upper heater 230. Alternatively, although not shown, the upper diffusion portion 210 may be provided inside the upper showerhead 200, and thus the upper diffusion portion 210 may not come into contact with the upper heater 230.

Accordingly, the inert gas supplied through the upper supply path 252 is diffused in the upper diffusion portion 210 and supplied downward through an upper through hole 212 of the upper showerhead 200.

The upper showerhead 200 may be connected to a radio frequency (RF) power supply 600 to supply RF power. That is, the upper showerhead 200 may function as an upper electrode.

When RF power is applied to the upper showerhead 200, the upper showerhead 200 may obtain capacitive coupling with the substrate W and a lower showerhead 430, and plasma may be generated between the lower surface of the substrate W and the lower showerhead 430, thereby cleaning the lower surface and bevel of the substrate W.

The substrate supporting member 400 described above may be provided to be moveable up and down at a lower portion of the processing space 110 to support an edge of the lower surface of the substrate W and to supply the process gas toward the lower surface of the substrate W, thereby cleaning the lower surface and bevel of the substrate W.

The substrate supporting member 400 may be connected to a driving bar 470 that extends downward, and the driving bar 470 may be connected to a driver (not shown) such as a motor to move the driving bar 470 and the substrate supporting member 400 upward and downward by driving of the driver.

In detail, the substrate supporting member 400 may include a substrate holder 410 that supports the lower surface of the edge of the substrate W, the lower showerhead 430 that supplies the process gas toward the lower surface of the substrate W, and a lift pin 500 that passes through the lower showerhead 430 and is moveable up and down. The substrate supporting member 400 may further include a lower plate 450 in which a heat exchange path 452 is formed.

The substrate holder 410 may support the lower surface of the edge of the substrate W. The substrate holder 410 may be supported by a fixing member 420 with a lower end connected to the lower plate 450.

The substrate holder 410 may extend upward from the fixing member 420 and may have a shape that is bent inward.

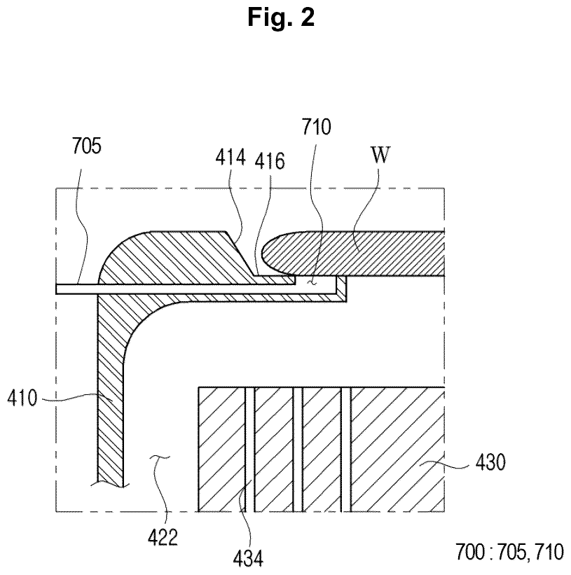

FIG. 2 is an enlarged diagram of an upper end of the substrate holder 410.

Referring to FIGS. 1 and 2, a support surface 416 that supports the lower surface of the edge of the substrate W and an inclined portion 414 inclined toward the support surface 416 may be provided at the upper end of the substrate holder 410. When the substrate W is accommodated on the support surface 416, the substrate W may be accurately supported by the support surface 416 by the inclined portion 414.

The lower showerhead 430 may be provided inside the substrate holder 410.

A process gas is supplied through a lower supply path 472 formed to pass through the driving bar 470 and the process gas supplied along the lower supply path 472 may be supplied to the lower showerhead 430 through a lower diffuser portion 432. The process gas supplied to the lower showerhead 430 is supplied toward the lower surface of the substrate W through a lower through hole 434.

In this case, the lower showerhead 430 may be grounded to generate plasma between the lower showerhead 430 and the substrate W.

A heat exchange path (not shown) may be formed in the lower plate 450, and a heat exchange fluid, or the like may flow along the heat exchange path to control the temperature of the process gas or the inside of the chamber 100 through heat exchange.

The lower plate 450 may support the lower showerhead 430 and the substrate holder 410.

In this case, the lower showerhead 430 may be connected to an upper surface of the lower plate 450, and the lower supply path 472 described above may be formed to pass through the driving bar 470 and the lower plate 450 and connected to the lower diffuser portion 432.

The fixing member 420 supporting the lower end of the substrate holder 410 may be connected to the lower plate 450.

In this case, the fixing member 420 may not completely connect the lower end of the substrate holder 410 to the lower plate 450, and the fixing member 420 may be provided in a plural number and spaced apart at a predetermined interval along an outer circumference of the lower plate 450.

That is, when the fixing member 420 is provided in a plural number, a space between adjacent fixing members 420 may be opened downward and may communicate with the inside of the chamber 100. Accordingly, a space between lateral surfaces of the lower showerhead 430 and the lower plate 450 and an inner surface of the substrate holder 410 may define an exhaust path 422.

In this case, the process gas supplied from the lower showerhead 430 may be discharged to a lower portion of the inside of the chamber 100 through the exhaust path 422 and exhausted to the outside of the chamber 100 through an exhaust 490 provided at the lower portion of the chamber 100.

A cleaning space 412 may be provided by the lower surface of the substrate W, an upper surface of the lower showerhead 430, and an upper inner wall of the substrate holder 410. In this case, the cleaning space 412 may not be a completely sealed space, but may be defined as a so-called “semi-sealed space” that is connected to the inside of the chamber 100 through the exhaust path 422 described above.

In the case of having the structure described above, a process gas may be supplied from the lower showerhead 430 to the cleaning space 412, and the process gas may be activated by plasma to clean the lower surface and bevel of the substrate W.

From among the process gases, the gas that remains after a cleaning process is discharged to the lower portion of the chamber 100 along the exhaust path 422 connected to the cleaning space 412, and is discharged to the outside of the chamber 100 through the exhaust 490 at the lower portion of the chamber 100.

The inert gas supplied from the upper showerhead 200 toward the upper surface of the substrate W may flow to the lower portion of the chamber 100 and be discharged to the outside of the chamber 100 through the exhaust 490.

Therefore, in the case of the substrate processing apparatus 1000 according to the present disclosure, to exhaust the inert gas supplied from the upper showerhead 200 and the process gas supplied from the lower showerhead 430, both the inert gas and the process gas may be exhausted by a single exhaust 490 instead of including a separate exhaust. By adopting the structure of the single exhaust 490, the configuration of the lower portion of the chamber 100 may be simplified, and the gas inside the chamber 100 may be exhausted through simple control.

The substrate holder 410 may include a floating unit 700 that supports the substrate W in a non-contact manner by floating the substrate W.

As described above, to prevent cleaning failure due to contact points of components such as the lift pin 500 or the substrate holder 410 on the lower surface of the substrate W without inverting the substrate W, the substrate processing apparatus 1000 according to the present disclosure may include the floating unit 700 for supporting the substrate W above the substrate holder 410 in a non-contact manner.

The substrate W may be supported in a non-contact manner by supplying a floating gas such as inert gas toward the lower surface of the edge of the substrate W to float the substrate W from the substrate holder 410.

That is, when the lower surface of the substrate W is cleaned by supporting the substrate W without the substrate W coming into contact with the substrate holder 410, a cleaning failure area in which cleaning is not performed may be reduced.

Referring to FIGS. 1 and 2, the floating unit 700 may include a plurality of supply holes 710 that are provided in the support surface 416 supporting the substrate W in the substrate holder 410 to supply the floating gas toward the lower surface of the substrate W, and a gas supply line 705 that supplies the floating gas to the supply holes 710.

The gas supply line 705 may extend from the outside of the chamber 100 to the inside of the chamber 100 and communicate with the supply holes 710 of the substrate holder 410. Although not shown in the drawing, the gas supply line 705 may be connected to the supply hole of the substrate holder 410 through the driving bar 470.

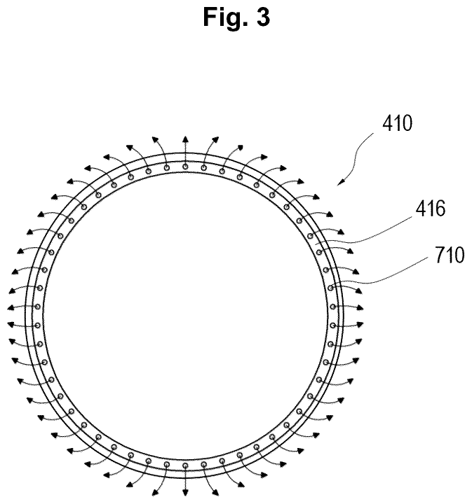

FIG. 3 is a plan view of the substrate holder 410 according to an embodiment.

Referring to FIGS. 2 and 3, the supply hole 710 may be provided in the support surface 416 of the substrate holder 410, on which the substrate W is accommodated. In this case, the supply hole 710 may be provided in a plural number along the support surface 416. The supply holes 710 may be provided on the lower surface of the edge of the substrate W along the support surface 416.

When the supply holes 710 are arranged as described above and a floating gas is supplied from the supply holes 710, the substrate W may be floated from the substrate holder 410 according to Bernoulli's equation.

In detail, the supply holes 710 may provide a swirl when supplying a floating gas to the lower surface of the substrate W. The substrate W may be floated by the swirl in the substrate holder 410.

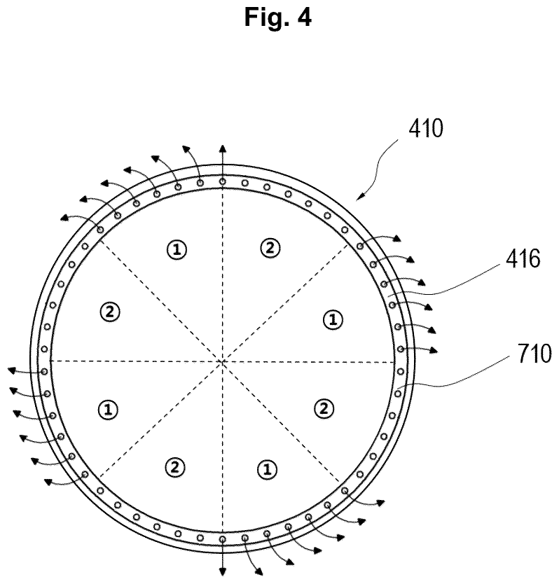

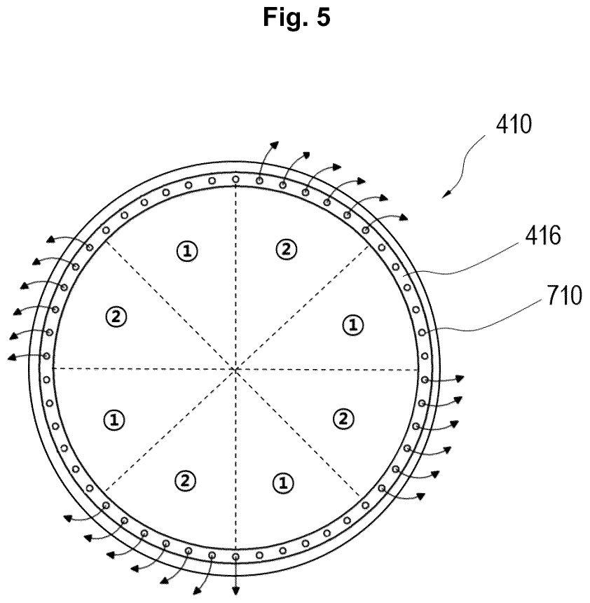

FIGS. 4 and 5 are plan views of the substrate holder 410 according to another embodiment.

The substrate holder 410 shown in FIGS. 4 and 5 may have the supply holes 710 divided into a plurality of supply areas. Although FIGS. 4 and 5 illustrate the supply holes 710 to be divided into two supply areas of a first supply area \textcircled{1} and a second supply area \textcircled{2}, this is merely an example and the supply holes 710 may be divided into three or more supply areas. Hereinafter, a case in which the supply holes 710 are divided into two supply areas will be described.

Referring to FIGS. 4 and 5, the supply holes 710 may be divided into two supply areas, and each supply area may alternately supply a floating gas. As such, when the lower surface and bevel of the substrate W are cleaned, the lower surface and bevel of the substrate W may be uniformly etched.

When the supply holes 710 are divided into a plurality of supply areas, the plurality of supply areas may be alternately arranged along a circumferential direction on the support surface 416 with respect to a central portion of the substrate holder 410. That is, the first supply area \textcircled{1} and the second supply area \textcircled{2} may be alternately arranged along a circumferential direction on the support surface 416 with respect to the central portion of the support surface 416.

The plurality of supply areas are illustrated as having approximately the same arc with respect to the central portion of the substrate holder 410, but are not limited thereto. For example, at least one of the plurality of supply areas constituting the plurality of supply areas may be configured to have a different arc length.

For example, the first supply area \textcircled{1} and the second supply area \textcircled{2} are illustrated as having approximately the same arc with respect to the central portion of the substrate holder 410, but are not limited thereto. For example, at least one of the plurality of supply areas constituting the first supply area \textcircled{1} and the second supply area \textcircled{2} may be configured to have a different arc length.

Directions of floating gas supplied from the supply holes 710 belonging to the first supply area \textcircled{1} and the second supply area \textcircled{2} may be formed to be the same or different from each other. For example, all of the floating gases supplied from the supply holes 710 belonging to the first supply area \textcircled{1} and the second supply area \textcircled{2} may be formed to provide a swirl. All of the floating gases supplied from the supply holes 710 belonging to the first supply area \textcircled{1} and the second supply area \textcircled{2} may be directed in different directions.

For example, when floating gases are supplied in the form of a swirl from all of the supply holes 710 as shown in FIG. 3 described above, the substrate W may be floated without rotating and supported on the substrate holder 410.

In this case, the plurality of supply holes 710 may be inclined in the same direction in a circumferential direction of the substrate W or inclined in different directions for the plurality of respective supply areas \textcircled{1} and \textcircled{2}.

FIG. 4 illustrates a state in which a floating gas is supplied from the supply holes 710 of the first supply area \textcircled{1}, and FIG. 5 illustrates a state in which a floating gas is supplied from the supply holes 710 of the second supply area \textcircled{2}.

As such, when the plurality of supply areas \textcircled{1} and \textcircled{2} alternately supply the floating gas, the substrate W may be supported in a non-contact manner while rotating.

For example, when the floating gas is alternately supplied from the supply holes 710 of the first supply area \textcircled{1} and the supply holes 710 of the second supply area \textcircled{2}, the substrate W may be supported in a non-contact manner while rotating.

In this case, a rotation amount of the substrate W may be controlled by controlling an injection time of the gas alternately supplied from the supply holes 710 of the first supply area \textcircled{1} and the supply holes 710 of the second supply area \textcircled{2}.

When the supply holes 710 belonging to each of the supply areas \textcircled{1} and \textcircled{2} alternately supply the floating gas to clean the lower surface of the substrate W, the process gas may be supplied between the substrate holder 410 and the edge of the substrate W by the lower showerhead 430 in the supply areas \textcircled{1} and \textcircled{2} in which the floating gas is not supplied, and thus the bevel of the substrate W may be evenly cleaned.

For example, in the case of FIG. 4, the floating gas is supplied from the supply holes 710 of the first supply area \textcircled{1}, and the floating gas is not supplied from the supply holes 710 of the second supply area \textcircled{2}. In this case, the process gas supplied by the lower showerhead 430 from the lower portion of the substrate W may be supplied to a space between the substrate holder 410 and the edge of the substrate W in a supply area in which the floating gas is not supplied, i.e., the second supply area \textcircled{2} to uniformly clean the bevel of the substrate W.

In FIG. 5, on the contrary, the floating gas is not supplied from the supply holes 710 of the first supply area \textcircled{1}, and the floating gas is supplied from the supply holes 710 of the second supply area \textcircled{2}. In this case, the process gas supplied by the lower showerhead 430 from the lower portion of the substrate W may be supplied to a space between the substrate holder 410 and the edge of the substrate W in an supply area in which the floating gas is not supplied, i.e., the first supply area \textcircled{1} to uniformly clean the bevel of the substrate W.

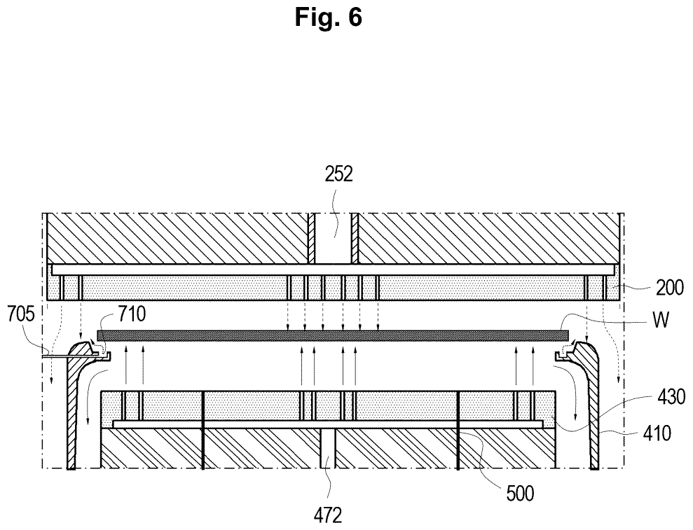

FIG. 6 is a side view showing a state in which the substrate W is supported and floated in a non-contact manner by the floating unit 700 described above.

Referring to FIG. 1 and FIG. 6, the substrate W may be introduced into the chamber 100 and loaded at the upper end of the lift pin 500. Then, the lift pin 500 may be lowered and the substrate W may be loaded on the support surface 416 of the substrate holder 410.

Then, the substrate W may be lifted to a process height. That is, with the substrate W loaded on the substrate holder 410, the substrate W may be lifted to the process height. This process height may be predetermined, and a distance between the substrate supporting member 400 and the upper showerhead 200 may be determined by the process height. Accordingly, the substrate supporting member 400 may be lifted to adjust an interval between the upper surface of the substrate W and the lower surface of the upper showerhead 200 to a predetermined interval. In this case, the interval may be determined as a fixed interval at which plasma is not generated between the upper surface of the substrate W and the lower surface of the upper showerhead 200 even when RF power is applied to the upper showerhead 200.

The substrate supporting member 400 may be lifted and then an inert gas may be supplied toward the upper surface of the substrate W. The inert gas may include N₂ but is not limited thereto.

The inert gas supplied along the upper supply path 252 provided at the upper portion of the chamber 100 may be supplied to the upper showerhead 200 through the upper diffusion portion 210.

The inert gas supplied to the upper showerhead 200 is supplied to the upper surface of the substrate W, thereby preventing the process gas or byproducts from flowing into the upper surface of the substrate W when performing a cleaning process on the lower surface and bevel of the substrate W.

The inert gas supplied to the upper surface of the substrate W flows to the lower portion of the chamber 100 in a radial direction of the substrate supporting member 400 as shown in FIG. 6 (dotted arrow) and is exhausted to the outside of the chamber 100 through the exhaust 490.

Then, the floating gas may be supplied through the supply holes 710 of the floating unit 700. In this case, the plurality of supply holes 710 are divided into the plurality of supply areas \textcircled{1} and \textcircled{2}, and the plurality of supply areas \textcircled{1} and \textcircled{2} may be arranged alternately along a circumferential direction with respect to the central portion of the substrate holder 410.

The floating gas may be supplied alternately toward the lower surface of the substrate W from the plurality of supply areas \textcircled{1} and \textcircled{2}.

That is, the floating gas is supplied toward the lower surface of the edge of the substrate W through the supply holes 710 of the substrate holder 410 to float the substrate W above the substrate holder 410. Accordingly, the substrate W is floated and supported above the substrate holder 410 in a non-contact manner.

After the above substrate W is supported in a non-contact manner, the process gas is supplied toward the lower surface of the substrate W through the lower showerhead 430. For example, the process gas may include NF₃ and Ar and may be modified in various ways.

In detail, the process gas is supplied through a lower supply path 472 formed to pass through the driving bar 470 and the process gas supplied along the lower supply path 472 may be supplied to the lower showerhead 430 through a lower diffuser portion 432. The process gas supplied to the lower showerhead 430 is supplied toward the lower surface of the substrate W through a lower through hole 434.

After the process gas is supplied toward the lower surface of the substrate W or at the same time when the process gas is supplied toward the lower surface of the substrate W, RF power may be applied to the upper showerhead 200 to generate plasma between the lower showerhead 430 and the lower surface of the substrate W.

When RF power is applied to the upper showerhead 200, capacitive coupling may be obtained between the upper showerhead 200 and the substrate W, and between the substrate W and the lower showerhead 430 to generate plasma between the lower surface of the substrate W and the lower showerhead 430. The process gas may be activated by the plasma to clean the lower surface and bevel of the substrate W.

In this case, some of the process gas supplied toward the lower surface of the substrate W may be discharged from the inside of the substrate supporting member 400 through the interval between the edge of the substrate W and the upper end of the substrate holder 410.

That is, the substrate W is floated by the floating unit 700 and supported in a non-contact manner, and thus some of the process gas may be discharged through the interval between the edge of the substrate W and the upper end of the substrate holder 410 while cleaning the bevel of the substrate W and the lower surface of the edge of the substrate W.

In particular, in the supply areas \textcircled{1} and \textcircled{2} in which the floating gas is not supplied, the process gas may be supplied to a space between the substrate holder 410 and the lower surface of the substrate W to uniformly clean the bevel of the substrate W.

In this case, although not shown in the drawing, an exhaust path for exhausting residual gas may be formed in the upper showerhead 200. That is, the remaining gas discharged through the interval between the edge of the substrate W and the upper end of the substrate holder 410 may be discharged to the outside of the chamber 100 through the exhaust path.

Some of the process gas may clean the lower surface of the substrate W and be exhausted to the lower portion of the inside of the chamber 100 through the exhaust path 422 described above of the inside the substrate holder 410. The residual gas or byproducts exhausted to the lower portion of the inside of the chamber 100 is exhausted to the outside of the chamber 100 through the exhaust 490.

As a result, the process gas supplied through the lower showerhead 430 may effectively clean the lower surface and bevel of the substrate W through plasma, and may not generate a cleaning failure area in which cleaning is not performed on the lower surface and bevel of the substrate W.

According to the present disclosure having the configuration described above, the lower surface and bevel of the substrate may be effectively cleaned by a simple configuration without requiring a separate component for inverting or raising the substrate.

According to the present disclosure, the substrate may be floated above the substrate holder according to Bernoulli's equation, thereby effectively cleaning the lower surface and bevel of the substrate without inverting the substrate and further without generating a contact point on the lower surface of the substrate.

Although the present disclosure has been described above with reference to exemplary embodiments, those skilled in the art may modify and change the present disclosure in various ways without departing from the spirit and scope of the present disclosure as set forth in the claims described below. Therefore, when the modified implementation basically includes the elements of the claims of the present disclosure, it should be considered to be included in the technical scope of the present disclosure.

What is claimed is:

1. A substrate processing apparatus comprising:
a chamber providing a processing space for a substrate;
an upper showerhead provided in the chamber configured to supply an inert gas toward an upper surface of the substrate and to which radio frequency (RF) power is applied; and
a substrate supporting member that supports a lower surface of an edge of the substrate to supply a process gas toward a lower surface of the substrate and cleans the lower surface and bevel of the substrate by using plasma,
wherein the substrate supporting member includes a substrate holder configured to support the lower surface of the edge of the substrate and a lower showerhead configured to supply the process gas toward the lower surface of the substrate, and
the substrate holder includes a floating unit configured to float the substrate.

2. The substrate processing apparatus of claim 1, wherein the floating unit includes a plurality of supply holes provided in a support surface supporting the substrate in the substrate holder and configured to supply a floating gas toward the lower surface of the substrate, and a gas supply line configured to supply the floating gas to the supply holes.

3. The substrate processing apparatus of claim 2, wherein the plurality of supply holes of the floating unit are divided into a plurality of supply areas.

4. The substrate processing apparatus of claim 3, wherein the plurality of supply areas are alternately arranged along a circumferential direction with respect to a central portion of the substrate holder.

5. The substrate processing apparatus of claim 4, wherein each supply area of the plurality of supply areas alternately supplies the floating gas.

6. The substrate processing apparatus of claim 5, wherein, when each supply area of the plurality of supply areas alternately supplies the floating gas and the process gas supplied by the lower showerhead cleans the lower surface of the substrate, the process gas is supplied to a space between the substrate holder and the lower surface of the substrate in the supply area in which the floating gas is not supplied and cleans the bevel of the substrate.

7. The substrate processing apparatus of claim 3, wherein lengths of arcs of the plurality of supply areas are equal to each other.

8. The substrate processing apparatus of claim 3, wherein the plurality of supply holes are inclined in the same direction along a circumferential direction of the substrate or are inclined in different directions for the plurality of respective supply areas.

9. A substrate processing method of cleaning a lower surface and bevel of a substrate, the method comprising:
loading the substrate on a substrate holder;
lifting the substrate to a process height;
supplying an inert gas toward an upper surface of the substrate;
floating the substrate by supplying a floating gas toward the lower surface of the substrate; and
cleaning the lower surface and bevel of the substrate by supplying a process gas toward the lower surface of the substrate.

10. The method of claim 9, wherein the floating of the substrate by supplying the floating gas toward the lower surface of the substrate includes supplying the floating gas toward a lower surface of the edge of the substrate through a plurality of supply holes formed in the substrate holder.

11. The method of claim 10, wherein the plurality of supply holes are divided into a plurality of supply areas and the plurality of supply areas are alternately arranged with respect to a central portion of the substrate holder, and
the floating gas is alternately supplied to the lower surface of the substrate in the plurality of supply areas.

12. The method of claim 11, wherein the supplying of the process gas toward the lower surface of the substrate includes supplying the process gas to a space between the substrate holder and the lower surface of the substrate in the supply area in which the floating gas is not supplied and cleaning the bevel of the substrate.

13. The method of claim 9, further comprising generating plasma on the lower surface of the substrate.
